(19) United States
(12) Patent Application Publication
(10) Pub. No.: US 2008/0310084 A1
(43) Pub. Date: Dec. 18, 2008

(54) PORTABLE ELECTRONIC DEVICE HAVING WRITING MECHANISM

(75) Inventor: CHENG-LUNG CHANG, Jen Te (TW)

Correspondence Address: PCE INDUSTRY, INC.;ATT. CHENG-JU CHIANG, 458 E. LAMBERT ROAD, FULLERTON, CA, 92835, US

(73) Assignee: CHI MEI COMMUNICATION SYSTEMS, INC., Tainan County (TW)

(21) Appl. No.: 11/933,955

(22) Filed: Nov. 1, 2007

(30) Foreign Application Priority Data
Jun. 15, 2007 (CN) 200710075058.2

(51) Int. Cl. H05K 5/00

(52) U.S. Cl. 361/679

(57) ABSTRACT

A portable electronic device (30) includes a first body (32), a second body (34), and a writing board (3222). The first body has a surface (322). The second body is movably mounted to the first body and covers the surface of the first body. The writing board is formed on the surface of the first body.

### BACKGROUND OF THE INVENTION

1. Field of the Invention

The present invention generally relates to portable electronic devices and, particularly, to a portable electronic device having writing mechanism for recording information.

2. Discussion of the Related Art

With the development of the technology of information processing, portable electronic devices such as mobile phones and other communication devices are now in widespread use. Such communication devices enable consumers to communicate with each other anytime and anywhere. However, when a user is out and needs to record information, the communication device is not convenient to quickly record information, and it is usually hard for the user to find a paper and a pencil.

In some electronic devices, a cavity is defined in a body of a given electronic device. The cavity is configured (i.e., structured and arranged) for receiving papers therein. A pencil is mounted to the body of the electronic device by a line. Thus, when a user needs to record information, he/she can take out the paper and use the pencil to write on the paper. However, the paper containing recorded information tends to be difficult to inserted again into the cavity and is likely to lose.

Therefore, a new portable electronic device is desired in order to overcome the above-described shortcoming.

### SUMMARY

In one aspect thereof, a portable electronic device includes a first body, a second body, and a writing board. The first body has a surface. The second body is movably mounted to the first body and covers the surface of the first body. The writing board is formed on the surface of the first body.

Other advantages and novel features of the embodiments will become more apparent from the following detailed description thereof when taken in conjunction with the accompanying drawings.

### BRIEF DESCRIPTION OF THE DRAWINGS

Many aspects of the present portable electronic device can be better understood with reference to the following drawings. The components in the drawings are not necessarily to scale, the emphasis instead being placed upon clearly illustrating the principles of the present portable electronic device. Moreover, in the drawings, like reference numerals designate corresponding parts throughout the several views.

FIG. 1 is a partially exploded, isometric view of a portable electronic device, in accordance with a first embodiment; and

FIG. 2 is a partially exploded, isometric view of a portable electronic device, in accordance with a second embodiment.

### DETAILED DESCRIPTION OF THE EMBODIMENT

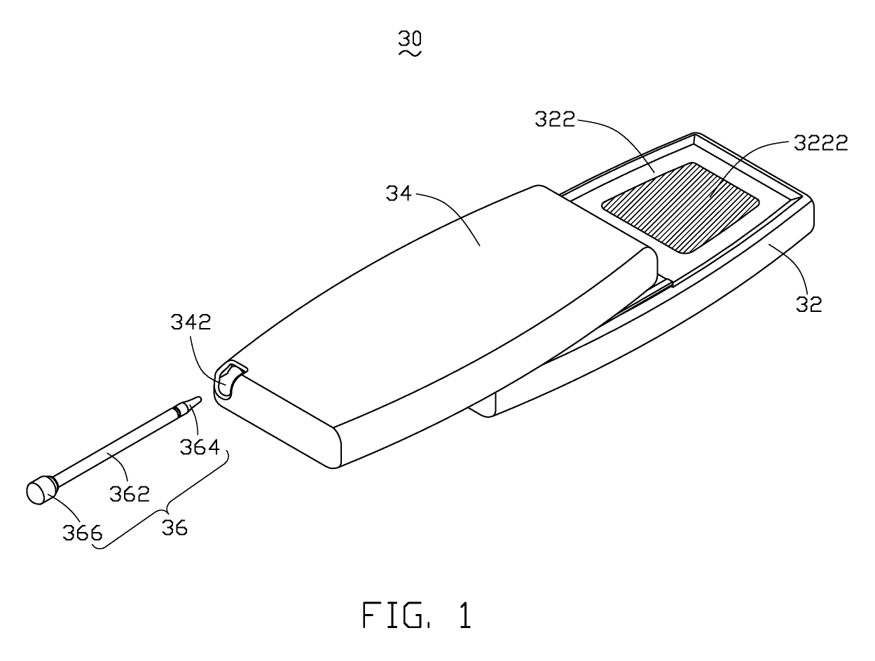

Referring now to the drawings in detail, FIG. 1 shows a portable electronic device 30 having a writing mechanism, according to a first embodiment. The writing mechanism includes a writing board 3222 and a writing tool 36. The writing board 3222 and the writing tool 36 are both provided on the portable electronic device 30.

The portable electronic device 30 includes a first body 32 and a second body 34. The first body 32 has a surface 322 at one side. The first body 32 and the second body 34 are substantially rectangular blocks. The second body 34 is configured for being slideable relative to the first body 32 to cover or uncover the surface 322. The second body 34 defines a receiving cavity 342 in one end thereof. The first body 32 and the second body 34 are both made of a plastic material. The plastic material may be polyvinyl chloride, polyethylene terephthalate, acrylonitrile-butadiene-styrene, polycarbonate, polyimide, liquid crystal polymer, polyetherimide, polyphenylene sulfide, polysulfone, polystyrene, glycol-modified polyester, polypropylene, or any desired combination thereof.

The writing board 3222 is formed on one end of the surface 322 of the first body 32. The writing board 3222 may be a blackboard, a white board, or a fluorescent board. Correspondingly, the writing tool 36 may be a watercolor pen or a fluorescent pen.

The writing tool 36 is configured for being receivable in the receiving cavity 342 of the second body 34. The writing tool 36 can be held in the second body 34 due to friction produced therebetween and can be taken out manually. The writing tool 36 includes a holder 362, a nib 364, and a wiper 366. The holder 362 is a long thin pole in shape. The nib 364 and the wiper 366 are respectively formed on two opposite ends of the holder 362. The nib 364 is configured for writing on the writing board 3222. The wiper 366 is configured for erasing and cleaning the writing board 3222.

When the user needs to record information, the writing tool 36 is taken out from the receiving cavity 342 of the second body 34. Meanwhile, the second body 34 is required to slide away from the first body 32 in order to expose the writing board 3222. The user can then record information on the writing board 3222 by using the writing tool 36. When the user does not need to record information, the second body 34 is required to slide back to cover the writing board 3222 and protect the recorded information from wiping off. When the information is not needed anymore, the user can use the wiper 366 of the writing tool 36 to erase and clean the writing board 3222.

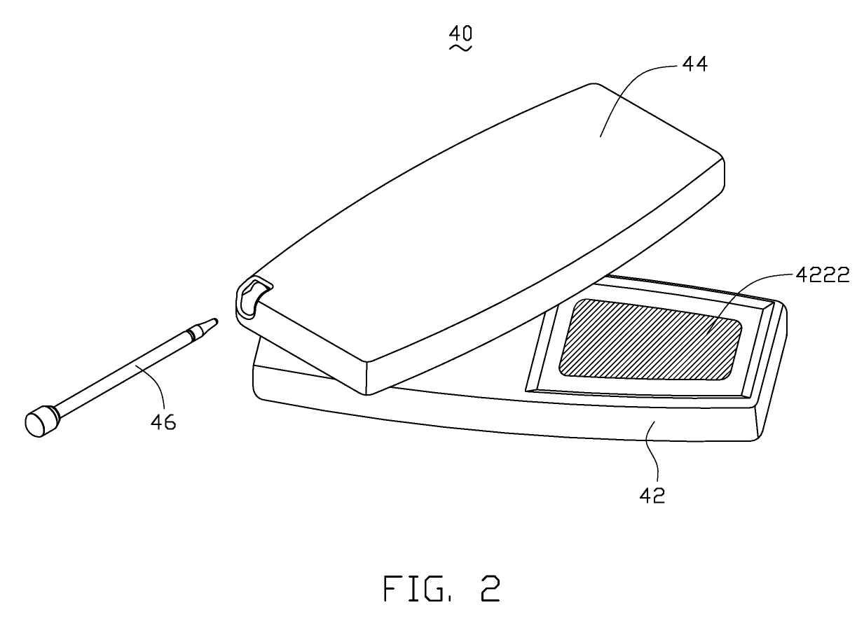

Referring to FIG. 2, a portable electronic device 40 having a writing mechanism according to a second embodiment is shown. The portable electronic device 40 is similar to the portable electronic device 30 of the first embodiment, having a first body 42, a second body 44, a writing board 4222, and a writing tool 46, except that the first body 42 is rotatable relative to the second body 44. The writing board 4222 is formed at one end of the first body 42. One end of the second body 44 is mounted to the first body 42 by a hinge (not shown) formed at an opposite end of the first body 42. The second body 44 can rotate due to the hinge along a plane, on which the second body 44 extends. Thus, the other end of the second body 44 can be moved away from the first body 42 thereby opposing the writing board 4222 to use.

It is to be understood that the receiving cavity may be formed in the first body. The writing tool may be separated from the portable electronic device.

It is to be understood, however, that even though numerous characteristics and advantages of the present embodiments have been set forth in the foregoing description, together with details of the structures and functions of the embodiments, the disclosure is illustrative only, and changes may be made in detail, especially in matters of shape, size, and arrangement of parts within the principles of the invention to the full extent indicated by the broad general meaning of the terms in which the appended claims are expressed.

What is claimed is:

1. A portable electronic device comprising:
a first body having a surface;
a second body mounted to the first body; and
a writing board formed on the surface of the first body, the second body being movable relative to the first body to selectively covering the writing board.

2. The portable electronic device as claimed in claim 1, further comprising a writing tool configured for being received by one of the first and second bodies and for writing on the writing board.

3. The portable electronic device as claimed in claim 2, wherein the writing tool is one of a watercolor pen and a fluorescent pen.

4. The portable electronic device as claimed in claim 3, wherein the writing board is one of a blackboard, a white board, and a fluorescent board.

5. The portable electronic device as claimed in claim 2, wherein one of the first body and the second body defines a receiving cavity therein, and the writing tool is configured for being receivable in the receiving cavity.

6. The portable electronic device as claimed in claim 2, wherein the writing tool includes a holder, a nib, and a wiper, and the nib and the wiper are respectively formed at two opposite ends of the holder.

7. The portable electronic device as claimed in claim 1, wherein the first body and the second body are substantially rectangular blocks and the first body is slidable relative to the second body.

8. The portable electronic device as claimed in claim 1, wherein the first body is rotatable relative to the second body.

9. The portable electronic device as claimed in claim 1, wherein one of the first body and the second body is made of a material selected from the group consisting of polyvinyl chloride, polyethylene terephthalate, acrylonitrile-butadiene-styrene, polycarbonate, polyimide, polyetherimide, polyphenylene sulfide, polysulfone, polystyrene, glycol-modified polyester, and polypropylene.
